(19) United States
(12) Patent Application Publication
(10) Pub. No.: US 2008/0101035 A1
(43) Pub. Date: May 1, 2008

(54) Heat-dissipating assembly structure

(76) Inventor: Chiung Yi Chen, Taipei (TW)

Correspondence Address: BIRCH STEWART KOLASCH & BIRCH, PO BOX 747, FALLS CHURCH, VA, 22040-0747, US

(21) Appl. No.: 11/586,636

(22) Filed: Oct. 26, 2006

(51) Int. Cl. H05K 7/20

(52) U.S. Cl. 361/720

(57) ABSTRACT

A heat-dissipating assembly structure includes a first heat dissipating sheet attached to one side of a memory module and having first hooks at one long side, a second heat dissipating sheet attached to the opposite side of the memory module and having second hooks at one long side respectively hooked up with the first hooks, and pairs of guide plates respectively provided at the same long side of the left heat dissipating sheet and the same long side of the right heat dissipating sheet at different elevations for guiding the first hooks into engagement with the second hooks during installation of the heat-dissipating assembly structure.

### BACKGROUND OF THE INVENTION

1. Field of the Invention

The present invention relates to a heat-dissipating assembly structure for memory module and more particularly, to such a heat-dissipating assembly structure that can easily and closely secured to the memory chips of a memory module to dissipate heat from the memory chips efficiently.

2. Description of the Related Art

Following fast development of high technology, advanced and high power IC chips are continuously created. However, a high-speed IC chip products much heat energy during operation. If heat energy is not rapidly removed from the surface of the IC chip during its operation, the IC chip may be unable to function normally or may burn out when the working temperature surpasses a predetermined level. Many heat dissipation devices have been produced for dissipating heat from semiconductor products. Subject to heat dissipation principle and the type of heat dissipation medium, regular heat dissipation devices include fan-heat-dissipating assemblies, radiation fin type heat dissipating assemblies, water-cooling heat dissipating assemblies, etc. A fan-heat-dissipating assembly uses a fan to cause currents of air toward the heat source (IC chip or hard disk drive), thereby carrying heat energy away from the heat source. However, a fan-heat-dissipating assembly is not practical for use in a narrow space area, or where the contact area between the heat source and the air is limited. When fan-heat-dissipating assembly is used in a narrow space area or where the contact area between the heat source and the air is limited, the amount of currents of air blowing toward the heat source at a unit of time is limited, resulting in low heat dissipation efficiency. Therefore, heat dissipating assemblies of materials that absorb and dissipate heat efficiently are developed. These heat dissipating assemblies enable absorbed heat energy to be evenly distributed over the surface, thereby increasing the contact area with the currents of air and effectively improving the heat dissipation efficiency. Therefore, these heat dissipating assemblies are practical for use in a device having a limited air contact surface, for example, a memory.

When a heat dissipating assembly is used in a memory, it is adhered to the surface of the memory and then secured firmly and closely to the surface of the memory by means of a special measure. FIG. 1 shows a typical design for conventional heat dissipating assembly. According to this design, two heat dissipating sheets 11 are respectively attached to the two opposite sides of a memory module R, and a clamp 10 is fastened to the heat dissipating sheets 11 to secure the heat dissipating sheets 11 to the memory module R firmly, keeping the heat dissipating sheets 11 in close contact with the memory chips R1 of the memory module R. This design of heat-dissipating assembly structure has a complicated structure. Further, the installation of this design of heat-dissipating assembly structure needs much labor.

Therefore, it is desirable to provide a heat-dissipating assembly structure that eliminates the aforesaid drawbacks.

### SUMMARY OF THE INVENTION

The present invention has been accomplished under the circumstances in view. It is the main object of the present invention to provide a heat-dissipating assembly structure, which can easily and closely be secured to the memory chips of a memory module to dissipate heat from the memory chips efficiently. It is another object of the present invention to provide a heat-dissipating assembly structure, which can easily and rapidly be assembled and installed.

To achieve these and other objects of the present invention, the heat-dissipating assembly structure comprises a left heat dissipating sheet and a right heat dissipating sheet respectively attached to left and right sides of a memory module, the left heat dissipating sheet and the right heat dissipating sheet being symmetric in shape; a plurality of first hooks respectively provided at one long side of the left heat dissipating sheet; a plurality of second hooks respectively provided at one long side of the right heat dissipating sheet corresponding to the first hooks and adapted to hook up with the first hooks respectively; and at least one first guide plate and at least one second guide plate respectively provided at the same long side of the left heat dissipating sheet and the same long side of the right heat dissipating sheet, the at least one first guide plate being movable along the at least one second guide plate to guide the first hooks into engagement with the second hooks.

The at least one first guide plate and the at least one second guide plate are respectively disposed at two different elevations so that the at least one first guide plate at one heat dissipating sheet is respectively moved over the at least one second guide plate at the other heat dissipating sheet to guide the first hooks into engagement with the second hooks.

The at least one first guide plate and at least one second guide plate are respectively extending from the corresponding long side of the left heat dissipating sheet and the corresponding long side of the right heat dissipating sheet at right angle. Further, the extending direction of the hooks is same as the extending direction of the guide plates at the same heat dissipating sheet.

### BRIEF DESCRIPTION OF THE DRAWINGS

FIG. 1 is a sectional view showing a heat-dissipating assembly structure fastened to a memory module according to the prior art.

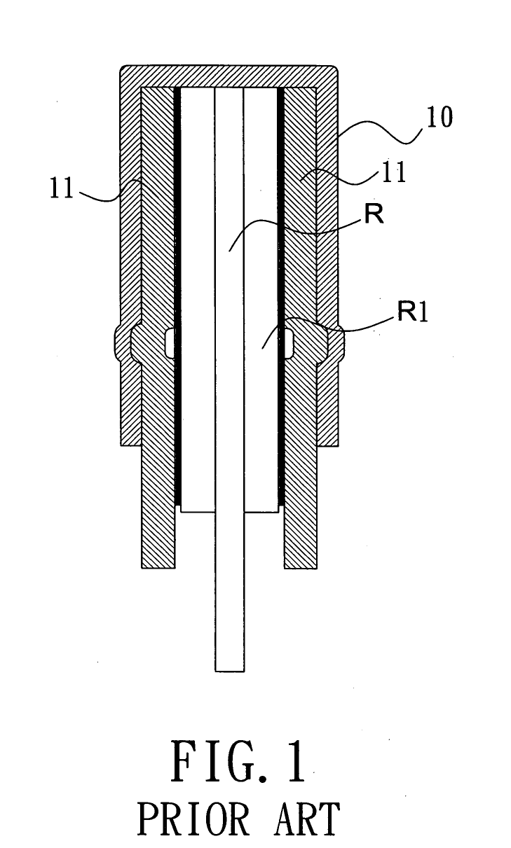

FIG. 2 is an exploded view of a heat-dissipating assembly structure according to the present invention.

FIG. 3 is a schematic top view of heat-dissipating assembly structure in the present invention, showing the relationship between the left and right heat dissipating sheets and the memory module before engagement between the first hooks and the second hooks.

FIG. 4 is a top view of heat-dissipating assembly structure in the present invention, showing the heat-dissipating assembly structure assembled.

FIG. 5 is an exploded view of an alternate form of the heat-dissipating assembly structure according to the present invention.

### DETAILED DESCRIPTION OF THE PREFERRED EMBODIMENT

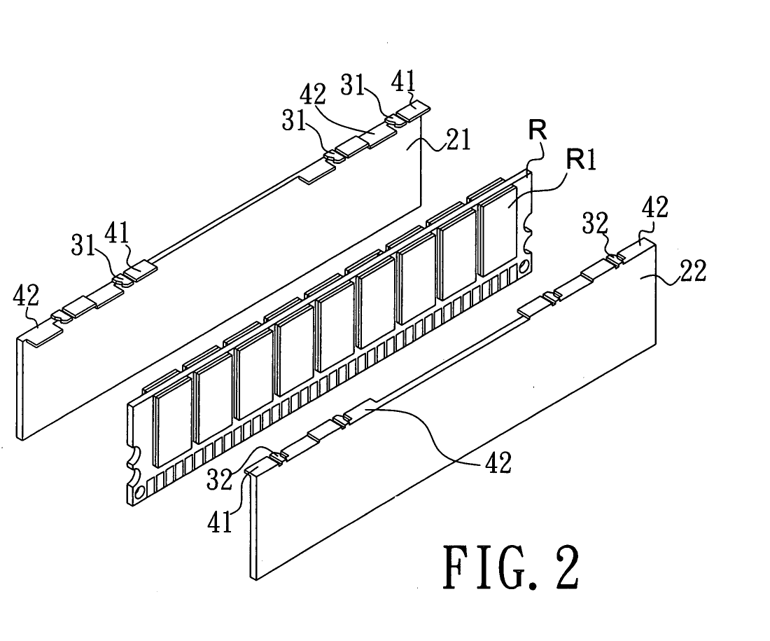

Referring to FIGS. 2˜4, a heat-dissipating assembly structure in accordance with the present invention is shown fastened to a memory module R and adapted to dissipate heat from the memory module R. The heat-dissipating assembly structure is comprised of a left heat dissipating sheet 21, a right heat dissipating sheet 22, first hooks 31, second hooks 32, and at least one guide plate pair each having a first guide plate 41 and a second guide plate 42 disposed at different elevations.

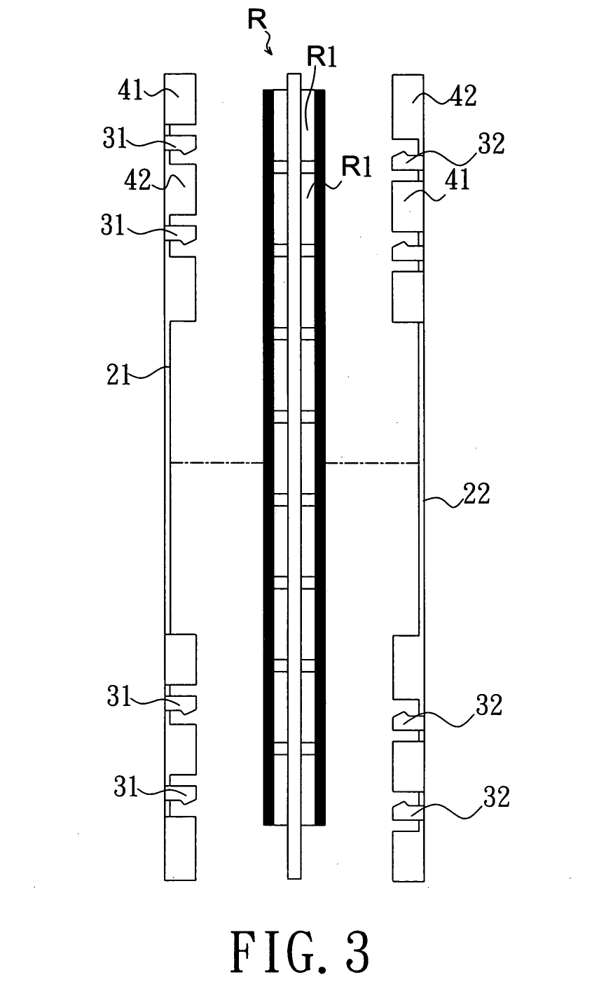

The left heat dissipating sheet 21 and the right heat dissipating sheet 22 are respectively attached to the left and right sides of the memory module R (see FIG. 3). The left heat dissipating sheet 21 and the right heat dissipating sheet 22 are made of copper or aluminum alloy for the advantage of high heat conductivity for quick dissipation of heat energy. Further, the left heat dissipating sheet 21 and the right heat dissipating sheet 22 have a rectangular shape and are symmetrically attached to the left and right sides of the memory module R.

The first hooks 31 and the second hooks 32 are respectively provided at one long side of the left heat dissipating sheet 21 and one long side of the right heat dissipating sheet 22, i.e., the first hooks 31 are provided at the left heat dissipating sheet 21 and the second hooks 32 are provided at the right heat dissipating sheet 22 at locations corresponding to the first hooks 31. According to this embodiment, the first hooks 31 and the second hooks 32 are respectively extended from the corresponding long side of the left heat dissipating sheet 21 and the corresponding long side of the right heat dissipating sheet 22 at right angle. The first hooks 31 and the second hooks 32 are respectively hooked up together to secure the left heat dissipating sheet 21 and the right heat dissipating sheet 22 firmly to the left and right sides of the memory module R, enabling the left heat dissipating sheet 21 and the right heat dissipating sheet 22 to dissipate heat from the memory module R efficiently during operation of the memory chips R1 of the memory module R.

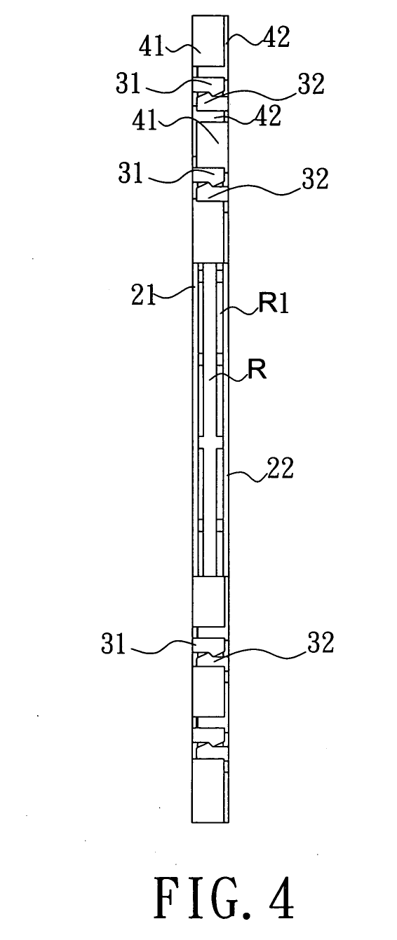

The first guide plates 41 and the second guide plates 42 are arranged in pairs and arranged at left heat dissipating sheet 21 and the right heat dissipating sheet 22 at two different elevations. According to this embodiment, the guide plates 41 and the second guide plates 42 are respectively extended from the corresponding long side of the left heat dissipating sheet 21 and the corresponding long side of the right heat dissipating sheet 22 at right angle. The first guide plates 41 are disposed at a relatively higher elevation than the second guide plates 42. Further, the first guide plates 41 at the left heat dissipating sheet 21 are respectively aimed at the second guide plates 42 at the right heat dissipating sheet 22, and the second guide plates 42 at the left heat dissipating sheet 21 are respectively aimed at the first guide plates 41 at the right heat dissipating sheet 22. During installation, the first guide plates 41 are respectively moved over the corresponding second guide plates 42 at the top to guide the respective first hooks 31 into engagement with the respective second hooks 32, thereby securing the left heat dissipating sheet 21 and the right heat dissipating sheet 22 firmly to the left and right sides of the memory module R (see FIG. 4) for the dissipation of heat from the memory module R.

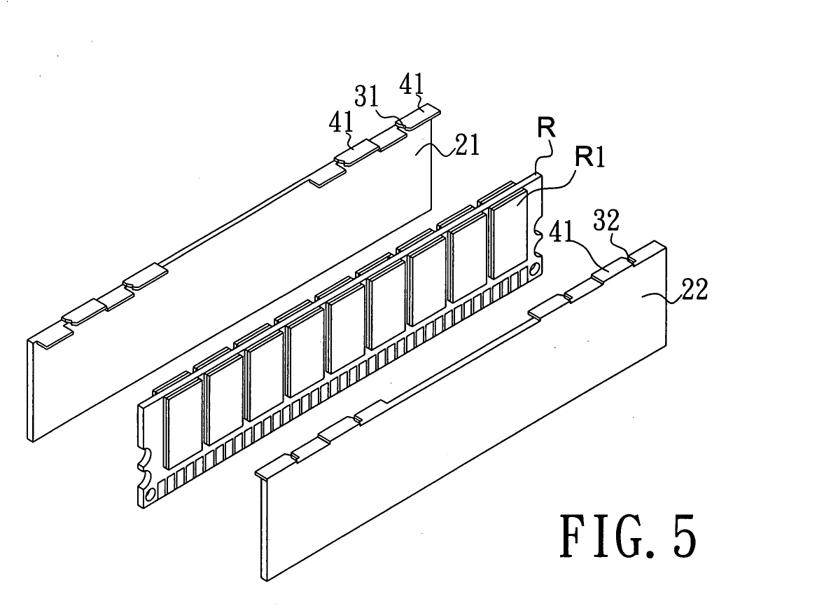

FIG. 5 is an exploded view of an alternate form of the heat-dissipating assembly structure according to the present invention. According to this embodiment, each first hook or second hook is formed integral with the adjacent guide plate.

As illustrated, the first hooks 31 and the second hooks 32 are respectively formed integral with the first guide plates 41 or the second guide plates 42, i.e., the first hooks 31 and the second hooks 32 are respectively extending from the associating first guide plates 41 at the left heat dissipating sheet 21 and right heat dissipating sheet 22. The first hooks 31 and the second hooks. 32 are respectively hooked together to secure the left heat dissipating sheet 21 and right heat dissipating sheet 22 to the left and right sides of the memory module R firmly.

During installation, an adhesive is applied to the memory chips R1 of the memory module R, and then the respective first guide plates 41 are respectively moved over the respective second guide plates 42 at the top to guide the respective first hooks 31 into engagement with the respective second hooks 32, thereby securing the left heat dissipating sheet 21 and the right heat dissipating sheet 22 to the left and right sides of the memory module R firmly. Further, the application of the adhesive is to keep the heat dissipating sheets 21 and 22 in close contact with the surface of the memory chips R1 of the memory module R, preventing gaps between the heat dissipating sheets 21 and 22 and the memory chips R1 of the memory module R that will lower the heat dissipation efficiency.

As indicated above, the benefit of the invention is: by means of hooking up the first hooks at the left heat dissipating with the second hooks at the right heat dissipating instead of the use of a clamp member in the prior art design, the left and right heat dissipating sheet are quickly fastened together and closely secured to the two opposite sides of the memory module. The design of the present invention greatly lowers the manufacturing cost and time.

A protocol of heat-dissipating assembly structure has been constructed with the features of FIGS. 2˜5. The heat-dissipating assembly structure functions smoothly to provide all of the features discussed earlier.

Although particular embodiment of the invention have been described in detail for purposes of illustration, various modifications and enhancements may be made without departing from the spirit and scope of the invention.

What the invention claimed is:

1. A heat-dissipating assembly structure comprising:
a left heat dissipating sheet and a right heat dissipating sheet respectively attached to left and right sides of a memory module, said left heat dissipating sheet and said right heat dissipating sheet being symmetric in shape;
a plurality of first hooks respectively provided at one long side of said left heat dissipating sheet;
a plurality of second hooks respectively provided at one long side of said right heat dissipating sheet corresponding to said first hooks and adapted to hook up with said first hooks respectively; and
at least one first guide plate and at least one second guide plate respectively provided at the same long side of said left heat dissipating sheet and the same long side of said right heat dissipating sheet, said at least one first guide plate being movable along said at least one second guide plate to guide said first hooks into engagement with said second hooks.

2. The heat-dissipating assembly structure as claimed in claim 1, wherein said least one first guide plate and at least one second guide plate are respectively extending from the corresponding long side of said left heat dissipating sheet and the corresponding long side of said right heat dissipating sheet at right angle.

3. The heat-dissipating assembly structure as claimed in claim 1, wherein said first hooks and said second hooks are respectively extending from the corresponding long side of said left heat dissipating sheet and the corresponding long side of said right heat dissipating sheet at right angle.

4. The heat-dissipating assembly structure as claimed in claim 1, wherein said first hooks and said second hooks are respectively formed integral with said at least one first guide plate and said at least one second guide plate.

5. The heat-dissipating assembly structure as claimed in claim 1, wherein said at least one first guide plate and said at least one second guide plate are respectively disposed at two different elevations.
